(19) United States
(12) Patent Application Publication
(10) Pub. No.: US 2026/0032870 A1
(43) Pub. Date: Jan. 29, 2026

(54) MAINBOARD LIQUID COOLING DEVICE AND DATA PROCESSING SYSTEM

(71) Applicant: Suzhou MetaBrain Intelligent Technology Co., Ltd., Suzhou, Jiangsu (CN)

(72) Inventors: CHANG MING KUAN, Suzhou, Jiangsu (CN); CHUN HSIEN WU, Suzhou, Jiangsu (CN)

(21) Appl. No.: 19/138,875

(22) PCT Filed: Sep. 29, 2024
(86) PCT No.: PCT/CN2024/122444

§ 371 Date: Jun. 13, 2025

(30) Foreign Application Priority Data
Dec. 20, 2023 (CN) 202311757505.8

(51) Int. Cl. H05K 7/20

(52) U.S. Cl. CPC H05K 7/20772

(57) ABSTRACT

Disclosed are a mainboard liquid cooling device and a data processing system, which relate to the technical field of servers. The mainboard liquid cooling device includes a base mechanism and at least one pair of heat dissipation mechanisms. The base mechanism is suitable to be fixed to a base plate; a flow channel for a liquid cooling medium is formed in the base mechanism; the pair of heat dissipation mechanisms are connected in a rotatable manner with the base mechanism through rotary mechanisms; the rotary mechanisms are of a hollow structure; and the heat dissipation mechanisms, the rotary mechanisms, and the base mechanism form a liquid cooling loop.

### CROSS-REFERENCE TO RELATED APPLICATION

This application claims priority to Chinese Patent Application No. 202311757505.8 filed on Dec. 20, 2023 with the China National Intellectual Property Administration and entitled “Mainboard Liquid Cooling Device and Data Processing System”, which is hereby incorporated by reference in its entirety.

### FIELD

The present disclosure relates to the technical field of servers, and specifically, to a mainboard liquid cooling device and a data processing system.

### BACKGROUND

Currently, with the improvement of computing power of servers, power consumption of processors in the servers is increasingly high, and the heat generated accordingly has been increased continuously. This leads to a continuous increase in the internal temperature of the server. To dissipate the heat of the processors and allow the processors to operate normally, liquid cooling devices are usually arranged on the processors, to dissipate the heat through a liquid closed loop.

However, to ensure a good heat dissipation effect of the liquid cooling device on the processor, the liquid cooling device is usually detachably mounted on the processor. During maintenance of the processor, technical personnel are required to manually dismount the liquid cooling device. After completing the maintenance of the processor, the technical personnel must manually reinstall the liquid cooling device on the processor.

Therefore, the maintenance process involves excessively cumbersome operating procedures, making it inconvenient for technical personnel to perform operations and resulting in low working efficiency.

### SUMMARY

In a first aspect, the present disclosure provides a mainboard liquid cooling device, which includes:
a base mechanism, suitable to be fixed to a base plate, and a flow channel for a liquid cooling medium being formed in the base mechanism; and
at least one pair of heat dissipation mechanisms, rotatably connected to the base mechanism through rotary mechanisms, the rotary mechanisms being of a hollow structure, and the heat dissipation mechanisms, the rotary mechanisms, and the base mechanism forming a liquid cooling loop.

Each of the rotary mechanisms includes a connecting pipe and a rotary sleeve; the connecting pipe is communicated with one of the heat dissipation mechanisms; one end of the rotary sleeve is connected with the connecting pipe, and the other end of the rotary sleeve is communicated with the base mechanism in a rotating manner; and the rotary sleeve and the base mechanism are rotatably sealed from each other.

The heat dissipation mechanisms, the base mechanism, and the base plate enclose a space for accommodating a device to be cooled.

In some embodiments, the heat dissipation mechanisms and the base mechanism are arranged perpendicular to each other in a same plane.

In some embodiments, the heat dissipation mechanisms and the base mechanism are arranged in parallel in a same plane.

In some embodiments,
a first water outlet and a first water inlet are formed on each of the heat dissipation mechanisms;
a second water outlet and a second water inlet are formed on the base mechanism;
the connecting pipe is connected with the first water outlets or the first water inlets;
one end of the rotary sleeve is connected with the connecting pipe, and the other end of the rotary sleeve is connected with the second water outlet or the second water inlet of the base mechanism in a rotating manner; and
when the rotary sleeve rotates relative to the second water outlet, sealing is maintained between the rotary sleeve and the second water outlet, and when the rotary sleeve rotates relative to the second water inlet, sealing is maintained between the rotary sleeve and the second water inlet.

In some embodiments, the connecting pipe is in threaded connection with the first water outlet or the first water inlet, and waterproof parts are arranged between the connecting pipe and the first water outlet and between the connecting pipe and the first water inlet.

In some embodiments, the rotary sleeve includes:
a sleeve body, which is of a hollow-cylinder-shaped structure, a first end portion of the sleeve body being suitable to interface with the connecting pipe, a second end portion of the sleeve body being suitable to be sleeved on the second water outlet or the second water inlet of the base mechanism, and the sleeve body and the second water outlet or the second water inlet of the base mechanism being rotatably sealed from each other; and
an internal threaded column, with the waterproof part sleeved thereon, the internal threaded column extending into the sleeve body, and protruding from the first end portion to allow the waterproof part to be located between the internal threaded column and the first end portion, a portion of the internal threaded column that protrudes from the first end portion being in threaded connection with the connecting pipe, and the internal threaded column being of a hollow structure.

In some embodiments, the waterproof part is a waterproof gasket.

In some embodiments, the base mechanism includes:
a liquid cooling base, suitable to be fixed to the base plate; and
a coolant manifold, arranged on the liquid cooling base, wherein the coolant manifold is provided with the flow channel for the liquid cooling medium, and the heat dissipation mechanisms being movably connected to the coolant manifold.

In some embodiments, the base mechanism further includes:
support seats, arranged on the base plate.

When located at heat dissipation positions, the heat dissipation mechanisms are abutted against the support seats.

In some embodiments, the base mechanism further includes:
ejecting members, arranged on the support seats.

When a pair of heat dissipation mechanisms move close to each other and are in the heat dissipation position, the heat dissipation mechanisms are abutted against the ejecting members, to allow the ejecting members to be in a compressed state; and
under an elastic force of the ejecting members, the heat dissipation mechanisms are ejected out of the heat dissipation positions, and under an external force, the pair of heat dissipation mechanisms move away from each other and are located at maintenance positions.

In some embodiments, each heat dissipation mechanism includes:
a heat sink, movably connected to the base mechanism; and
a locating assembly, arranged on the heat sink.

When the pair of heat dissipation mechanisms are in the heat dissipation positions, the locating assembly has a first position for interlocking the pair of heat dissipation mechanisms, and a second position for separating the pair of heat dissipation mechanisms from each other; and
when the locating assembly is located at the second position, under the elastic force of the ejecting members, the heat dissipation mechanisms are ejected out of the heat dissipation positions.

In some embodiments, the locating assembly includes:
a locating pin, arranged on one of the pair of heat dissipation mechanisms; and
a locating hole, formed on the other of the pair of heat dissipation mechanisms.

When the pair of heat dissipation mechanisms are in the heat dissipation positions, the locating pin is suitable to be inserted into the locating hole, to interlock the pair of heat dissipation mechanisms, and the locating pin is suitable to be pulled out of the locating hole, to separate the pair of heat dissipation mechanisms from each other.

In some embodiments, each heat dissipation mechanism further includes:
a handle, detachably arranged on the heat sink; and the locating hole is formed on the handle.

In some embodiments, the handle is provided with snap-fit clips, and the heat sink is provided with retention slots for receiving the snap-fit clips.

In some embodiments, the mainboard liquid cooling device further includes:
a first foam pad, arranged on the heat sink, and abutted against the heat sink when the heat sink is in the heat dissipation position, thereby forming a gap between the heat sink and the device to be cooled; and
second foam pads, arranged on the heat sink, and abutted against the base plate when the heat sink is in the maintenance position.

In some embodiments, the mainboard liquid cooling device further includes:
a water pump assembly, arranged on the liquid cooling base, and communicated with the coolant manifold.

In some embodiments, the water pump assembly includes:
a water pump, arranged on the liquid cooling base, and communicated with the coolant manifold; and
a fixing plate, covering the water pump and connected with the liquid cooling base.

In some embodiments, the water pump assembly further includes:
a temperature sensor, arranged on the heat sink, being in communication connection with the water pump, configured to detect a current temperature of the heat sink, and the water pump adjusting a flow rate of the liquid cooling medium based on the current temperature.

In some embodiments, when the heat dissipation mechanisms and the base mechanism are arranged in parallel in the same plane, the handle of one heat dissipation mechanism is provided with a protrusion, and the handle of the other heat dissipation mechanism is provided with a groove suitable for receiving the protrusion.

When the pair of heat dissipation mechanisms are stacked, the protrusion on the handle of one heat dissipation mechanism is inserted into the groove on the handle of the other heat dissipation mechanism, and the pair of heat dissipation mechanisms are kept at the maintenance positions.

In a second aspect, the present disclosure also provides a data processing system, which includes a device to be cooled, and the mainboard liquid cooling device in any one of the above implementations. The device to be cooled is arranged in a space enclosed by the heat dissipation mechanisms, the base mechanism, and the base plate.

### BRIEF DESCRIPTION OF THE DRAWINGS

In order to describe the technical solutions in the specific implementations of the present disclosure or in the prior art more clearly, the drawings required to be used in the specific implementations or in the prior art will be simply introduced below. It is apparent that the drawings described below are some implementations of the present disclosure. Other drawings may be obtained by those of ordinary skill in the art according to these drawings without creative work.

FIG. 1 is a schematic diagram of a whole structure of a mainboard liquid cooling device according to an embodiment of the present disclosure;

FIG. 2 is an exploded schematic diagram of the mainboard liquid cooling device shown in FIG. 1;

FIG. 3 is a schematic diagram of the mainboard liquid cooling device shown in FIG. 1, where a cooling fan is arranged thereon;

FIG. 4 is a side view of the mainboard liquid cooling device shown in FIG. 1, where heat dissipation mechanisms are in heat dissipation positions;

FIG. 5 is a side view of the mainboard liquid cooling device shown in FIG. 1, where heat dissipation mechanisms are in maintenance positions;

FIG. 6 is a schematic diagram of the mainboard liquid cooling device shown in FIG. 1, where only one of a pair of heat dissipation mechanisms is opened;

FIG. 7 is a schematic diagram of the mainboard liquid cooling device shown in FIG. 1, where a pair of heat dissipation mechanisms are opened;

FIG. 8 is an exploded schematic diagram of a heat dissipation mechanism according to an embodiment of the present disclosure;

FIG. 9 is a schematic diagram of assembling a heat dissipation mechanism and a base mechanism according to an embodiment of the present disclosure;

FIG. 10 is a schematic diagram of assembling a water pump assembly and a base mechanism according to an embodiment of the present disclosure;

FIG. 11 is a schematic diagram of another arrangement of a heat dissipation mechanism and a base mechanism according to an embodiment of the present disclosure;

FIG. 12 is another schematic diagram of FIG. 11, where only one of a pair of heat dissipation mechanisms is opened;

FIG. 13 is another schematic diagram of FIG. 11, where a pair of heat dissipation mechanisms are opened; and

FIG. 14 is a schematic diagram of the coordination of two handles in FIG. 11.

### DETAILED DESCRIPTION

To make objectives, technical solutions, and advantages of the embodiments of the present disclosure more clear, the technical solutions in the embodiments of the present disclosure will be clearly and completely described below with reference to the drawings in the embodiments of the present disclosure. It is apparent that the described embodiments are not all embodiments but only part of the embodiments of the present disclosure. All other embodiments obtained by those skilled in the art on the basis of the embodiments in the present disclosure without creative work shall fall within the scope of protection of the present disclosure.

In the description of the present disclosure, it should be noted that orientations or positional relationships indicated by terms “center”, “upper”, “lower”, “left”, “right”, “vertical”, “horizontal”, “inside”, “outside”, and the like are based on the orientations or positional relationships shown in the drawings, only for facilitating description of the present disclosure and simplifying the description, rather than indicating or implying that the devices or elements must have specific orientations or must be constructed and operated in specific orientations, and thus may not be interpreted as limitation to the present disclosure. In addition, terms “first”, “second” and “third” are only for description, and cannot be construed as indication or implication of relative importance.

In the description of the present disclosure, it should be noted that unless otherwise expressly specified and limited, the terms “mounted”, “linked” and “connected” are to be interpreted broadly, and may be, for example, fixedly connected, detachably connected, or integrally connected, may be mechanically or electrically connected, may be directly connected, or indirectly connected through an intermediate medium, may also be internally communicated between two elements, and may be connected in a wireless or wired manner. Those of ordinary skill in the art may understand specific meanings of the above terms in the present disclosure according to specific situations. In addition, the following described technical features involved in various implementations of the present disclosure can be combined as long as they are not conflicted.

For this purpose, the present disclosure provides a mainboard liquid cooling device and a data processing system, to solve a problem that a maintenance process involves excessively cumbersome operating procedures.

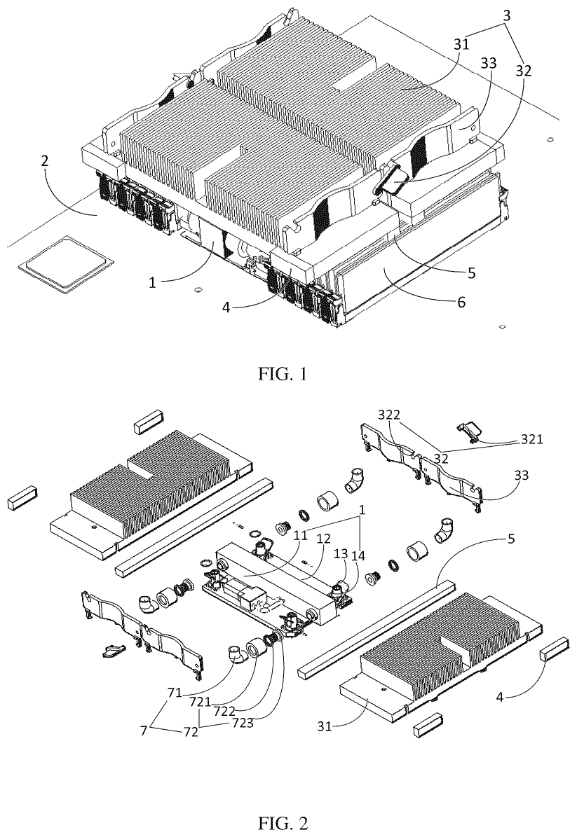

The embodiments of the present disclosure are described below with reference to FIG. 1 to FIG. 14.

In an aspect, an embodiment of the present disclosure provides a mainboard liquid cooling device, which includes a base mechanism 1 and heat dissipation mechanisms 3.

Specifically, in the embodiment of the present disclosure, as shown in FIG. 1, the base mechanism 1 is fixed to a base plate 2, and a connection mode of the base plate may be welding, threaded connection, or fixation through snap-fit clips. Of course, the embodiment merely provides an illustrative example of the connection mode of the base plate, but is not intended for limiting this. Those skilled in the art may make modifications according to actual circumstances, provided that the same technical effects may be achieved.

Further, a flow channel for a liquid cooling medium is formed in the base mechanism 1. That is, the base mechanism 1 is pre-configured with a hollow structure, and the hollow structure serves as the flow channel for the liquid cooling medium. Alternatively, a liquid cooling pipeline is arranged first, and then the liquid cooling pipeline is collectively arranged in the hollow structure. In this way, a pipeline layout is concise, which facilitates maintenance operation of technical personnel.

Further, in the embodiment of the present disclosure, the heat dissipation mechanisms 3 are arranged in pairs, and for the number of the heat dissipation mechanisms 3, the heat dissipation mechanisms 3 may be arranged in one pair, two pairs, three pairs, etc. Of course, the embodiment merely provides an illustrative example of the number of pairs of the heat dissipation mechanisms 3, but is not intended for limiting this. Those skilled in the art may make modifications according to actual circumstances, provided that the same technical effects may be achieved.

Moreover, the heat dissipation mechanisms 3 are movably connected to the base mechanism 1, and are communicated with the base mechanism 1. For example, the heat dissipation mechanisms 3 may be connected with the base mechanism 1 through communicating pipes, and dynamic seal structures may be configured to seal between the communicating pipes and the heat dissipation mechanisms 3, and between the communicating pipes and the base mechanism 1. In this way, a communicated state may be maintained while a movable connection is achieved. Of course, the communicating pipes may also be made of a flexible material, as long as interfaces between the communicating pipes and the heat dissipation mechanisms 3 and between the communicating pipes and the base mechanism 1 are sealed.

The embodiment merely provides an illustrative example of a connection mode of the heat dissipation mechanisms 3 and the base mechanism 1, but is not intended for limiting this. Those skilled in the art may make modifications according to actual circumstances, provided that the same technical effects may be achieved.

For the connection mode of the heat dissipation mechanisms 3 and the base mechanism 1, the heat dissipation mechanisms 3 may be connected with the base mechanism 1 through rotary mechanisms 7 in a rotatable manner. The rotary mechanisms 7 are of a hollow structure, and the heat dissipation mechanisms 3, the rotary mechanisms 7, and the base mechanism 1 form a liquid cooling loop. The rotary mechanisms 7 may be corrugated pipes, flexible connecting pipes 71, or pipelines capable of achieving a rotary seal. Of course, the embodiment merely provides an illustrative example of a type of the rotary mechanisms 7, but is not intended for limiting this. Those skilled in the art may make modifications according to actual circumstances, provided that the same technical effects may be achieved.

The rotary mechanisms 7 may serve as a bearing, thereby facilitating smooth rotational movement between the heat dissipation mechanisms 3 and the base mechanism 1. Meanwhile, the rotary mechanisms 7 may also serve as a pipeline, and the liquid cooling loop may be communicated through the hollow structure in each rotary mechanism 7, without additional arrangement of a liquid cooling pipeline, whereby a whole structure of each heat dissipation mechanism 3 may be simplified, which facilitates mounting and maintenance by the technical personnel. Further, a rotating component may be arranged on each of two sides of the base mechanism 1, whereby the heat dissipation mechanisms 3 may be securely confined in the base mechanism 1 by rotating components on the two sides. In this way, heat dissipation mechanisms 3 are prevented from being separated from the base mechanism 1 during rotation, and the rotating components have a certain limiting function to ensure normal operation of the device.

In some embodiments, each rotary mechanism 7 includes a connecting pipe 71 and a rotary sleeve 72. Specifically, the connecting pipe 71 is communicated with one of the heat dissipation mechanisms 3; one end of the rotary sleeve 72 is connected with the connecting pipe 71, and the other end of the rotary sleeve 72 is communicated with the base mechanism 1 in a rotating manner; and the rotary sleeve 72 and the base mechanism 1 are rotatably sealed, that is, the rotary sleeve and the base mechanism are in a rotary seal state through a dynamic seal structure, to ensure that the liquid cooling medium is not leaked during rotation, and the whole device may operate normally.

In some embodiments, as shown in FIG. 1, the heat dissipation mechanisms 3, the base mechanism 1, and the base plate 2 enclose a space for accommodating a device to be cooled 6, and the heat dissipation mechanisms 3 dissipate heat of the device to be cooled 6. That is, the base mechanism 1 is fixed to the base plate 2, and the heat dissipation mechanisms 3 may cover the base mechanism 1. In this configuration, the base mechanism 1 is located on a side face, the base plate 2 is located on a bottom, and the heat dissipation mechanisms 3 are located on a top, thereby enclosing the space. In the space, the device to be cooled 6 may be arranged, and is allowed to be located as close as possible to the heat dissipation mechanisms 3, thereby maximizing a heat dissipation effect of the heat dissipation mechanisms 3.

In some embodiments, during actual operation, when the heat dissipation mechanisms 3 are required to be maintained, under an external force, the heat dissipation mechanisms 3 are operated to rotate, and the heat dissipation mechanisms rotate relative to the base mechanism 1, thereby gradually rotating from positions covering the device to be cooled 6. Meanwhile, with the assistance of the rotary mechanisms 7, the heat dissipation mechanisms 3 finally rotate to positions exposing the device to be cooled 6. Similarly, when maintenance of the heat dissipation mechanisms 3 is completed, the heat dissipation mechanisms 3 may be operated to rotate, and the heat dissipation mechanisms 3 rotate relative to the base mechanism 1, thereby gradually rotating from the positions exposing the device to be cooled 6, and with the assistance of the rotary mechanisms 7, the heat dissipation mechanisms 3 finally rotate to the positions covering the device to be cooled 6.

For the type of external force, for example, the technical personnel may manually move the heat dissipation mechanisms 3, or operate the heat dissipation mechanisms 3 to move through a driving device. Of course, the embodiment merely provides an illustrative example of a source of the external force, but is not intended for limiting this. Those skilled in the art may make modifications according to actual circumstances, provided that the same technical effects may be achieved.

In the embodiment of the present disclosure, the heat dissipation mechanisms 3 are movably arranged, and the heat dissipation mechanisms 3 may expose or cover the device to be cooled 6 during rotation. Therefore, during actual maintenance, the technical personnel do not need to dismount the heat dissipation mechanisms 3, and simply need to move the heat dissipation mechanisms 3 from the heat dissipation positions to the maintenance positions, thereby directly exposing the device to be cooled 6. The technical personnel either do not need to remove the heat dissipation mechanisms 3 to other positions, and simply need to rotate and move the heat dissipation mechanisms 3 to the maintenance positions, and the heat dissipation mechanisms are located within their own movement ranges, without occupying positions of other components, thereby saving space; and additionally, operating procedures may be greatly decreased, thereby facilitating operation of the technical personnel and improving working efficiency.

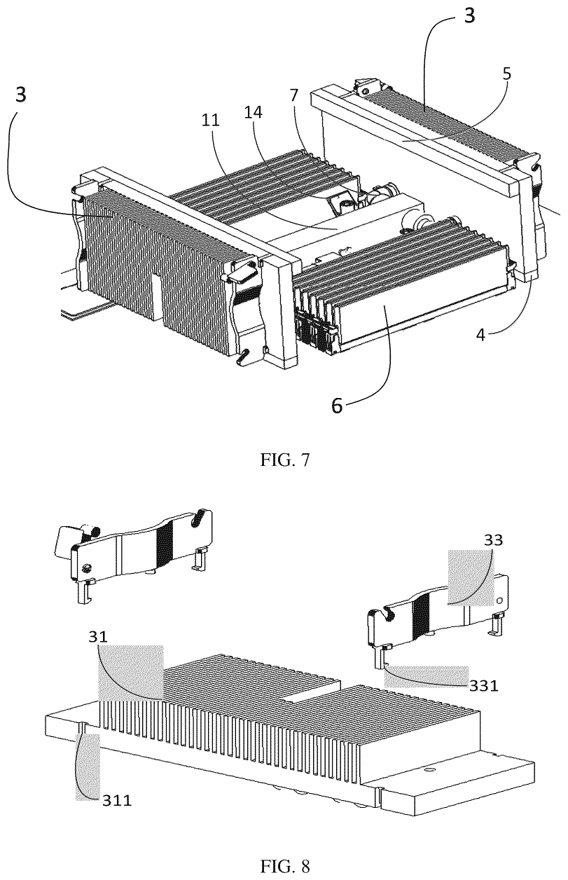

In some embodiments, the heat dissipation mechanisms 3 and the base mechanism 1 are arranged perpendicular to each other in a same plane. As shown in FIG. 7, a length direction of the base mechanism 1 is perpendicular to a length direction of each of the heat dissipation mechanisms 3. Under the external force, a pair of heat dissipation mechanisms 3 have the maintenance positions for moving away from each other and exposing the device to be cooled 6, and the heat dissipation positions for moving close to each other and covering the device to be cooled 6.

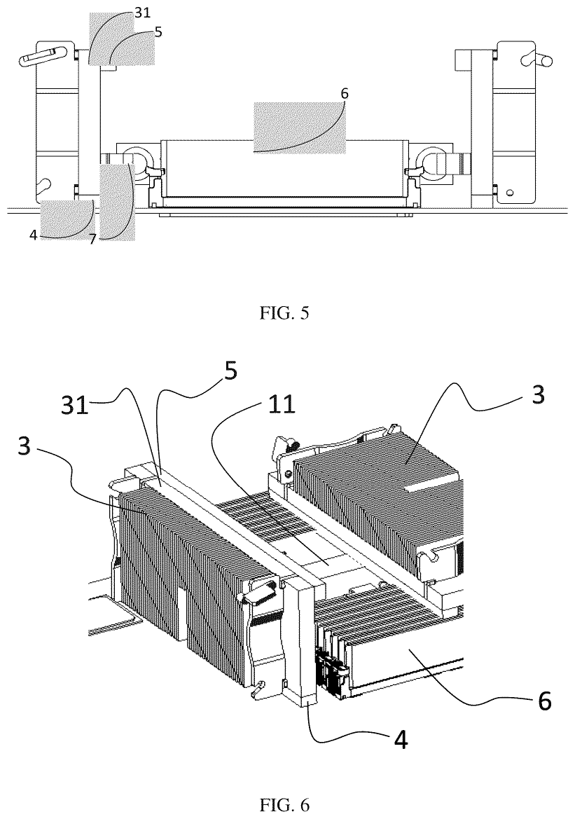

Specifically, the heat dissipation mechanism 3 is arranged at each end of the base mechanism 1 along its length direction, as shown in FIG. 5 and FIG. 7, and when two heat dissipation mechanisms 3 are respectively in the maintenance position, the two heat dissipation mechanisms 3 and the base mechanism 1 form an I-shaped structure. As shown in FIG. 1 and FIG. 4, when the two heat dissipation mechanisms 3 are in the heat dissipation positions, the two heat dissipation mechanisms 3 may completely cover the base mechanism 1, and form a stacked structure when viewed from outside.

Further, in the embodiment of the present disclosure, the heat dissipation mechanisms 3 and the base mechanism 1 are arranged perpendicular to each other in the same plane, and during maintenance, the heat dissipation mechanisms 3 are simply required to be opened from a side face, and do not need to occupy a utilization space in a vertical direction, thereby improving a space utilization rate of the whole device. Moreover, a mode that the heat dissipation mechanisms 3 are opened from the side face may significantly facilitate operation of the technical personnel compared with a mode that the heat dissipation mechanisms 3 are opened in other directions. Meanwhile, the center of gravity of the whole device is low, thereby preventing the heat dissipation mechanisms 3 from tipping over in any direction, which in turn ensures stable operation of the device.

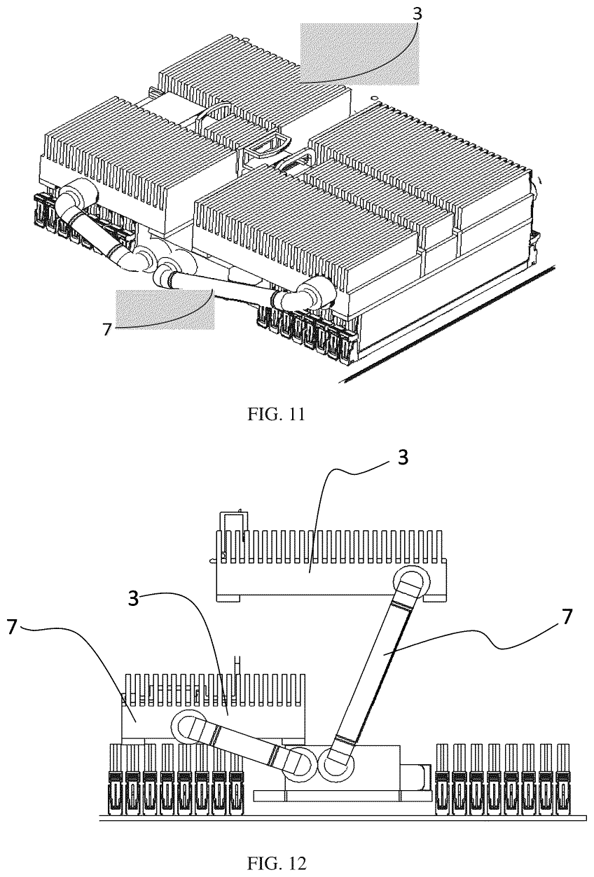

Further, in some embodiments, as shown in FIG. 11 to FIG. 14, another arrangement of the heat dissipation mechanisms 3 and the base mechanism 1 is provided. If the space on two sides of the heat dissipation mechanisms 3 is limited, and the heat dissipation mechanisms may not be normally opened in the above arrangement, the another arrangement that the heat dissipation mechanisms 3 and the base mechanism 1 are arranged in parallel in a same plane may be adopted.

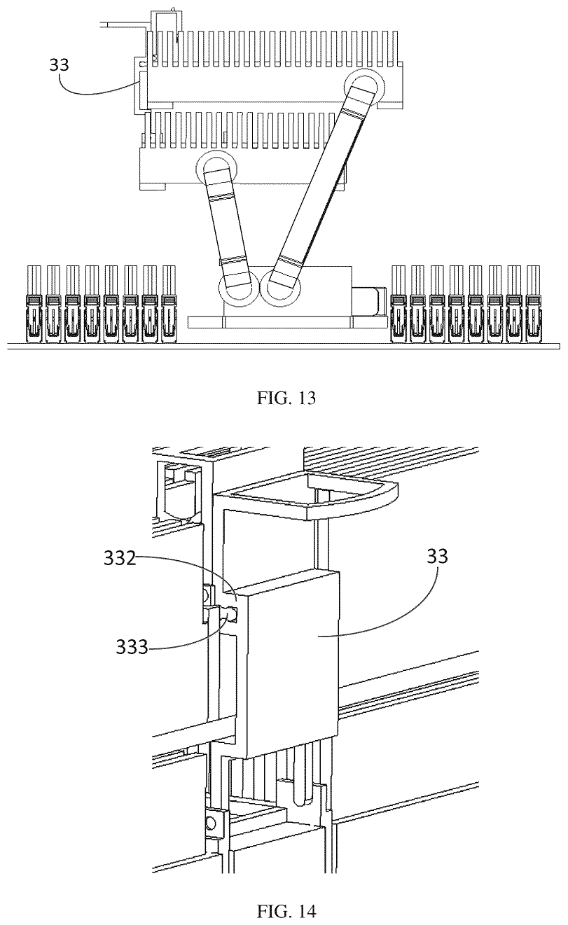

As shown in FIG. 13, under the external force, the pair of heat dissipation mechanisms 3 have the maintenance positions for moving away from the base mechanism 1, and for exposing the device to be cooled 6 when the heat dissipation mechanisms are stacked. The pair of heat dissipation mechanisms 3 have the heat dissipation positions for moving close to the base mechanism 1, and for covering the device to be cooled 6 when the heat dissipation mechanisms 3 return to original positions.

Similarly, the heat dissipation mechanisms 3 are connected in a rotatable manner with the base mechanism 1 through the rotary mechanisms 7, the rotary mechanisms 7 are of a hollow structure, and the heat dissipation mechanisms 3, the rotary mechanisms 7, and the base mechanism 1 form the liquid cooling loop.

In the embodiment of the present disclosure, the heat dissipation mechanisms 3 and the base mechanism 1 are arranged in parallel in the same plane, and during maintenance, the heat dissipation mechanisms 3 are simply required to be lifted directly from two sides, are not required to be opened from the two sides, and do not need to occupy a utilization space in a horizontal direction, thereby improving the space utilization rate of the whole device. Moreover, the heat dissipation mechanisms 3 are lifted directly from the two sides, which facilitates operation of the technical personnel.

Further, in some embodiments, a water outlet and a water inlet are formed on each heat dissipation mechanism 3, and a second water outlet and a second water inlet are formed on the base mechanism 1. As shown in FIG. 2, specifically, the connecting pipe 71 is connected with the first water outlets or the first water inlets, one end of the rotary sleeve 72 is connected with the connecting pipe 71, and the other end of the rotary sleeve 72 is connected with the second water outlet or the second water inlet of the base mechanism 1 in a rotating manner. That is, the connecting pipe 71 of a first rotary mechanism 7 is communicated with the first water outlet, and after one end of the rotary sleeve 72 of the first rotary mechanism 7 is connected with the connecting pipe 71 of the first rotary mechanism 7, the other end of the rotary sleeve 72 of the first rotary mechanism 7 is communicated with the second water inlet. The connecting pipe 71 of a second rotary mechanism 7 is communicated with the first water inlet, and after one end of the rotary sleeve 72 of the second rotary mechanism 7 is connected with the connecting pipe 71 of the second rotary mechanism 7, the other end of the rotary sleeve 72 of the second rotary mechanism 7 is communicated with the second water outlet.

In this way, the liquid cooling medium in the base mechanism 1 flows into the first water inlet of each heat dissipation mechanism 3 from the second water outlet, and then flows into the second water inlet of the base mechanism 1 from the first water outlet of each heat dissipation mechanism 3, thereby ensuring that the heat dissipation mechanisms 3 and the base mechanism 1 form a liquid cooling loop, and allowing the heat dissipation mechanisms 3 to operate normally.

Further, when the rotary sleeve 72 rotates relative to the second water outlet, a sealed state is maintained between the rotary sleeve and the second water outlet, and when the rotary sleeve 72 rotates relative to the second water inlet, a sealed state is maintained between the rotary sleeve and the second water inlet. Dynamic seal structures may be arranged between the rotary sleeve 72 and the second water outlet and between the rotary sleeve 72 and the second water inlet.

In the embodiment of the present disclosure, the rotary sleeve 72 is arranged, and the rotary sleeve may serve as a rotatory bearing while guiding the liquid cooling medium, may reduce friction generated between the heat dissipation mechanisms 3 and a liquid cooling mechanism during rotation, and ensure that the technical personnel may smoothly perform maintenance. Additionally, reduction of friction may also reduce wear of the heat dissipation mechanisms 3 and the liquid cooling mechanism during use, and prolong service life of the heat dissipation mechanisms and the liquid cooling mechanism. Further, the dynamic seal structures, such as rotary seals, may ensure that the liquid cooling medium is not leaked during rotation, whereby the whole device may operate normally.

Further, in some embodiments, the connecting pipe 71 is in threaded connection with the first water outlet or the first water inlet, and waterproof parts 723 are arranged between the connecting pipe 71 and the first water outlet and between the connecting pipe 71 and the first water inlet. The waterproof parts 723 may be waterproof gaskets, and may also be waterproof adhesive coatings. Of course, the embodiment merely provides an illustrative example of a type of the waterproof parts 723, but is not intended for limiting this. Those skilled in the art may make modifications according to actual circumstances, provided that the same technical effects may be achieved.

In the embodiment of the present disclosure, the waterproof parts 723 are arranged, sealing between the rotating components and the water inlet may be further ensured on the basis of arranging the rotary seals, and the liquid cooling medium is prevented from flowing out from a gap between the connecting pipe 71 and the base mechanism 1 during use, thereby preventing the base plate 2 and electronic devices on the base plate 2 from being damaged, and improving a safety of the whole device. Moreover, the waterproof parts 723 may be the waterproof gaskets, which may serve as a seal, and do not occupy an excessive internal space, and when the mainboard liquid cooling device is arranged inside a server, a space utilization rate inside the server may be improved to some extent.

Further, in some embodiments, as shown in FIG. 2, the rotary sleeve 72 includes a sleeve body 721 and an internal threaded column 722. Specifically, the sleeve body 721 is of a hollow-cylinder-shaped structure, a first end portion of the sleeve body 721 is suitable to interface with the connecting pipe 71, and a second end portion of the sleeve body 721 is suitable to be sleeved on the second water outlet or the second water inlet of the base mechanism 1. The sleeve body 721 and the second water outlet or the second water inlet of the base mechanism 1 are rotatably sealed.

In addition, the internal threaded column 722 is sleeved with a waterproof part 723, which extends into the sleeve body 721, and protrudes from the first end portion to allow the waterproof part 723 to be located between the internal threaded column 722 and the first end portion. A portion of the internal threaded column 722 that protrudes from the first end portion is in threaded connection with the connecting pipe 71, and when the internal threaded column 722 is completely screwed onto the connecting pipe 71, the waterproof part 723 is clamped between a head edge of the internal threaded column 722 and an inner edge of the first end portion, and the head edge, the waterproof part 723, and the inner edge are fitted to one another to achieve sealing between the internal threaded column 722 and the connecting pipe 71. The internal threaded column 722 is of a hollow structure, whereby the sleeve body 721 is kept communicated with the connecting pipe 71.

In the embodiment of the present disclosure, the internal threaded column 722 is arranged, and may detachably connect the sleeve body 721 and the connecting pipe 71, and during replacement and maintenance, the sleeve body 721 and the connecting pipe 71 may be respectively replaced and maintained according to actual situations, and are not required to be directly replaced as a whole or subjected to extensive maintenance as a whole, thereby saving materials to some extent. Moreover, the internal threaded column 722 is of the hollow structure, may have a fixing function, and may also have a guiding function, thereby eliminating the need to form threads on the sleeve body 721 for connection with the connecting pipe 71, and in this way, water leakage of the rotary sleeve 72 due to thread wear is prevented, thereby improving sealing of the whole device.

Further, in some embodiments, the waterproof part 723 is a waterproof gasket.

Further, in some embodiments, the base mechanism 1 includes a liquid cooling base 12 and a coolant manifold 11. Specifically, in the embodiment of the present disclosure, as shown in FIG. 2, the liquid cooling base 12 is suitable to be fixed to the base plate 2, and the liquid cooling base 12 may be welded to the base plate 2, may also be connected to the base plate 2 through a screw, and may also be snap-fitted to the base plate 2 through a snap-fit clip. Of course, the embodiment merely provides an illustrative example of a type of the waterproof parts 723, but is not intended for limiting this. Those skilled in the art may make modifications according to actual circumstances, provided that the same technical effects may be achieved.

Further, in the embodiment of the present disclosure, the coolant manifold 11 is arranged on the liquid cooling base 12, the flow channel for the liquid cooling medium is formed in the coolant manifold 11, and the heat dissipation mechanisms 3 are movably connected to the coolant manifold 11. The coolant manifold 11 is of a square tube structure, and the flow channel inside the coolant manifold 11 is configured for circulation of the liquid cooling medium. The coolant manifold 11 may be made of a PVC material or an aluminum alloy with better heat dissipation performance. Of course, the embodiment merely provides an illustrative example of the material of the coolant manifold 11, but is not intended for limiting this. Those skilled in the art may make modifications according to actual circumstances, provided that the same technical effects may be achieved.

In the embodiment of the present disclosure, the coolant manifold 11 is arranged, and may integrate an outlet pipe and inlet pipe for the liquid cooling medium together, without the need to additionally arrange the outlet pipe and inlet pipe special for the liquid cooling medium, thereby saving cost to some extent in an aspect of planning. Moreover, since the heat dissipation mechanisms 3 are movably connected to the coolant manifold 11, the liquid cooling pipeline may have a certain support function for the heat dissipation mechanisms 3, prevent the heat dissipation mechanisms 3 at the heat dissipation positions from directly attaching to the device to be cooled 6, and ensure normal operation of the device to be cooled 6.

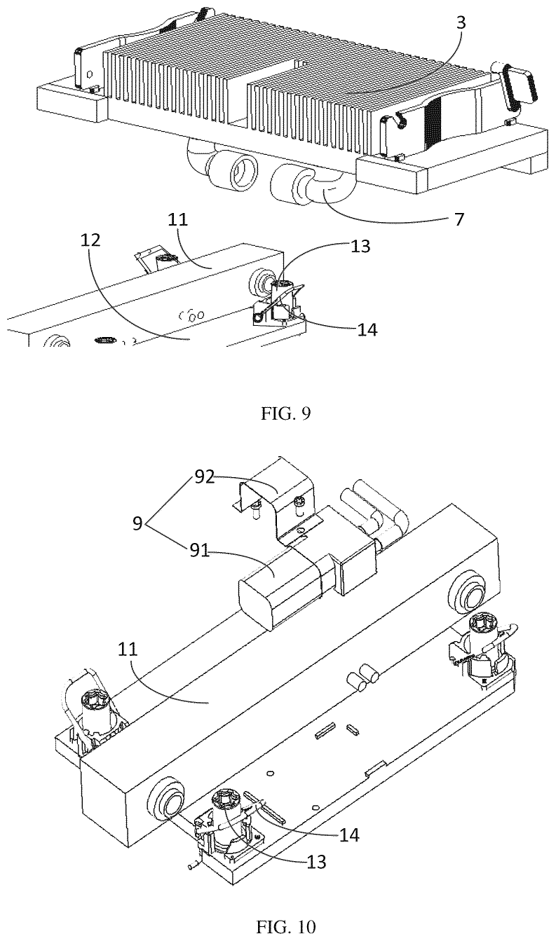

Further, in some embodiments, as shown in FIG. 2, FIG. 7, FIG. 9, and FIG. 10, the base mechanism 1 further includes support seats 13, and the support seats 13 are arranged on the base plate 2. When the heat dissipation mechanisms 3 are in the heat dissipation positions, the heat dissipation mechanisms 3 are abutted against the support seats 13. To ensure uniform stress of the heat dissipation mechanisms 3, the support seats 13 may be arranged at equal intervals on two sides of the coolant manifold 11 in a length direction. Additionally, buffer members may also be arranged on end faces, close to the heat dissipation mechanisms 3, of the support seats 13, and may transition from a rigid contact between the support seats 13 and the heat dissipation mechanisms 3 to a flexible contact, to achieve certain protection and buffer effects.

In the embodiment of the present disclosure, the support seats 13 are arranged, and when the heat dissipation mechanisms 3 are in the heat dissipation positions, the support seats 13 and the coolant manifold 11 may simultaneously support the heat dissipation mechanisms 3, thereby reducing pressures of the heat dissipation mechanisms 3 on the coolant manifold 11. During prolonged use, a degree of deformation of the coolant manifold 11 generated due to the pressures may be reduced, and normal operation of the whole device is ensured. Meanwhile, because the support seats 13 are arranged, the technical personnel may directly determine falling point positions of the heat dissipation mechanisms 3 through the support seats 13 during maintenance, and thus may directly move the heat dissipation mechanisms 3, to conveniently operate the heat dissipation mechanisms 3.

Further, in some embodiments, the base mechanism 1 further includes ejecting members 14, and the ejecting members 14 are arranged on the support seats 13. When the pair of heat dissipation mechanisms 3 move close to each other and are in the heat dissipation positions, the heat dissipation mechanisms 3 are abutted against the ejecting members 14, to allow the ejecting members 14 to be in a compressed state. When the ejecting members 14 are transitioned from the compressed state to a reset state, and under an elastic force of the ejecting members 14, the heat dissipation mechanisms 3 are ejected out of the heat dissipation positions. Then under the external force, the pair of heat dissipation mechanisms 3 move away from each other and are in the maintenance positions.

In the embodiment of the present disclosure, the ejecting members 14 are arranged, and when the technical personnel intend to operate the heat dissipation mechanisms 3 to maintain the device to be cooled 6, the technical personnel may directly operate the ejecting members 14, and the heat dissipation mechanisms 3 are ejected out of the heat dissipation positions, whereby the technical personnel may conveniently move the heat dissipation mechanisms 3, and simply need to move the heat dissipation mechanisms 3, without taking other unnecessary unlocking actions. Further, when completing maintenance, the technical personnel may move the heat dissipation mechanisms 3 from the maintenance positions to the heat dissipation positions again, to allow the ejecting members 14 to return to its original position, thereby enabling the heat dissipation mechanisms 3 to resume dissipating heat from the device to be cooled 6. In this way, operating steps of the technical personnel are simplified, and working efficiency may be improved to some extent.

Further, in some embodiments, as shown in FIG. 1 and FIG. 2, each heat dissipation mechanism 3 includes a heat sink 31 and a locating assembly 32. Specifically, in the embodiment of the present disclosure, the heat sink 31 is movably connected to the base mechanism 1, the locating assembly 32 is arranged on the heat sink 31, and the locating assembly 32 is movably connected to the heat sink 31.

During actual operation, when the pair of heat dissipation mechanisms 3 are in the heat dissipation positions, the locating assembly 32 has a first position for interlocking the pair of heat dissipation mechanisms 3, and a second position for separating the pair of heat dissipation mechanisms 3 from each other. When the locating assembly 32 is in the first position, the heat dissipation mechanisms 3 may not change positions, and are locked to the base mechanism 1. When the locating assembly 32 is in the second position, because the heat dissipation mechanisms 3 are not confined by other mechanisms, the heat dissipation mechanisms 3 may move from the heat dissipation positions to the maintenance positions. Moreover, as the ejecting members 14 are also arranged, the ejecting members 14 may not eject the heat dissipation mechanisms 3 from the heat dissipation positions when the heat dissipation mechanisms 3 are locked to the base mechanism 1. When the locating assembly 32 is in the second position, the heat dissipation mechanisms 3, which may move flexibly, are ejected out of the heat dissipation positions under the elastic force of the ejecting members 14.

In the embodiment of the present disclosure, the locating assembly 32 is arranged, and when completing maintenance, the technical personnel may move the heat dissipation mechanisms 3 from the maintenance positions to the heat dissipation positions again to allow the ejecting members 14 to return to its original position, and fix the pair of heat dissipation mechanisms 3 by using the locating assembly 32, thereby allowing the heat dissipation mechanisms 3 to resume dissipating heat from the device to be cooled 6. In this way, operating steps of the technical personnel are simplified, and the working efficiency may be improved to some extent. Further, when the technical personnel intend to operate the heat dissipation mechanisms 3 to maintain the device to be cooled 6, the technical personnel may directly operate the locating assembly 32 to separate the pair of heat dissipation mechanisms 3 from each other, and the heat dissipation mechanisms 3 may automatically eject from the heat dissipation positions under the elastic force of the ejecting members, whereby the technical personnel may conveniently move the heat dissipation mechanisms 3, and simply need to move the heat dissipation mechanisms 3, without taking other unnecessary unlocking actions.

Further, in some embodiments, as shown in FIG. 2 and FIG. 4, the locating assembly 32 includes a locating pin 321 and a locating hole 322. Specifically, in the embodiment of the present disclosure, the locating pin 321 is movably arranged on one of the pair of heat dissipation mechanisms 3, and the locating hole 322 is formed on the other of the pair of heat dissipation mechanisms 3.

During actual operation, when the pair of heat dissipation mechanisms 3 are in the heat dissipation positions, the locating pin 321 is suitable to be inserted into the locating hole 322, to interlock the pair of heat dissipation mechanisms 3. The locating pin 321 is suitable to be pulled out of the locating hole 322, to separate the pair of heat dissipation mechanisms 3 from each other.

In the embodiment of the present disclosure, the locating pin 321 and the locating hole 322 are arranged, and when completing maintenance, the technical personnel may move the heat dissipation mechanisms 3 from the maintenance positions to the heat dissipation positions again to allow the ejecting members 14 to return to its original position, and move the locating pin 321 into the locating hole 322 to fix the pair of heat dissipation mechanisms 3, thereby enabling the heat dissipation mechanisms 3 to resume dissipating heat from the device to be cooled 6. In this way, the operating steps of the technical personnel are simplified, and the working efficiency may be improved to some extent. Further, when the technical personnel intend to operate the heat dissipation mechanisms 3 to maintain the device to be cooled 6, the technical personnel may directly remove the locating pin 321 from the locating hole 322, to separate the pair of heat dissipation mechanisms 3 from each other; and the heat dissipation mechanisms 3 may automatically eject from the heat dissipation positions under the elastic force of the ejecting members, whereby the technical personnel may conveniently move the heat dissipation mechanisms 3, and simply need to move the heat dissipation mechanisms 3, without taking other unnecessary unlocking actions.

Further, in some embodiments, each heat dissipation mechanism 3 further includes a handle 33, the handle 33 is detachably arranged on the heat sink 31, and the locating hole 322 is formed on the handle 33.

In the embodiment of the present disclosure, the handle 33 is arranged, and when operating the heat sink 31, the technical personnel may directly contact the handle 33, thereby preventing burns caused by a high operating temperature of the heat sink 31. Meanwhile, the technical personnel may perform operation conveniently without the need for an operating tool, thereby simplifying the operating steps of the technical personnel and improving the working efficiency to some extent.

Further, in some embodiments, as shown in FIG. 8, snap-fit clips 331 are arranged on the handle 33, and retention slots 311 suitable for receiving the snap-fit clips 331 are formed on the heat sink 31. The handle 33 may be made of a resilient metal material, snap-fit clips 331 are arranged on two sides of a bottom of the handle 33, and the retention slots 311 are formed on two sides of a bottom of the heat sink 31. In this way, when the handle 33 moves downward and is completely inserted in the bottom of the heat sink 31, under an elastic force of the handle 33, the snap-fit clips 331 are completely engaged into the retention slots 311, so as to complete assembly of the handle 33.

When the handle 33 is dismounted, the snap-fit clips 331 may be pulled reversely, and after the snap-fit clips 331 are completely disengaged from the retention slots 311, the handle 33 may be moved reversely to separate from the heat sink 31.

Further, in some embodiments, as shown in FIG. 4, FIG. 5, and FIG. 7, the mainboard liquid cooling device further includes a support member arranged on the heat sink 31. The support member may include one support member arranged on a bottom face, facing the device to be cooled 6, of the heat sink 31, and when the heat sink 31 is in the heat dissipation position, a gap is reserved between the heat sink 31 and the device to be cooled 6. The support member may also include another support member arranged on a side face of the heat sink 31. For example, when the heat sink 31 is in the maintenance position, the another support member supports the heat sink 31 to prevent each rotary mechanism 7 from being damaged.

Specifically, the support member may include a first foam pad 5 and second foam pads 4. The first foam pad 5 is arranged on the heat sink 31. The first foam pad 5 is abutted against the device to be cooled 6 when the heat sink 31 is in the heat dissipation position, whereby the gap is formed between the heat sink 31 and the device to be cooled 6. The second foam pads 4 are arranged on the heat sink 31, and the second foam pads 4 are abutted against the base plate 2 when the heat sink 31 is in the maintenance position.

In the embodiment of the present disclosure, by arranging the first foam pad 5, the gap may be formed between the heat sink 31 and the device to be cooled 6 when the heat sink 31 is in the heat dissipation position. When an airflow generated by a cooling fan 8 of the mainboard liquid cooling device cools the heat sink 31, the airflow may pass through the gap, so as to accelerate a cooling rate of the device to be cooled 6 and improve a heat dissipation effect. Moreover, the second foam pads 4 provide support for the heat sink 31 when the heat sink 31 is in the maintenance position, thereby preventing damage to each rotary mechanism 7 caused by an excessive gravitational force of the heat sink 31 and ensuring normal use of the whole device.

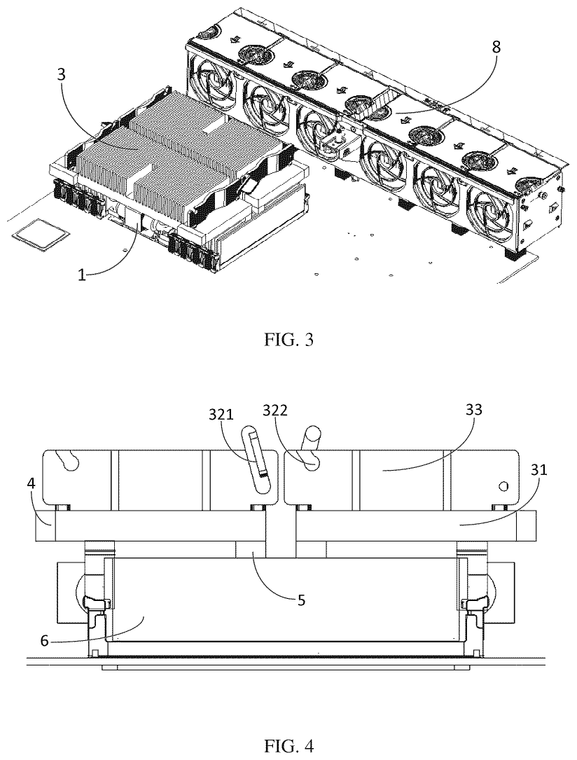

Further, in the embodiment of the present disclosure, as shown in FIG. 3, the cooling fan 8 is also arranged, and is configured for performing additional air cooling on the heat sink 31. To ensure a stability of the whole device, the cooling fan 8 and the base plate 2 may further be secured. The cooling fan 8 and the base plate 2 may be fixedly connected, or detachably connected. A fixed connection mode may be welding, gluing, or the like. A detachable connection may be fixation in a screw and screw hole mode, in a snap-fit clip and slot mode, and in a magnetic sheet attraction mode.

The detachable connection mode is illustrated below. For example, fixing plates may be additionally arranged on a periphery of an edge of the base plate 2, and those skilled in the art may change the number of the fixing plates to 1, 2, 3, 4, and etc. according to an actual situation. A screw hole may be formed in each fixing plate and a corresponding screw hole may be formed on the cooling fan 8. A screw is inserted sequentially through the screw hole on the fixing plate and the screw hole on the cooling fan 8 to connect the base plate 2 and the cooling fan 8. Further, during fixation in the snap-fit clip and slot mode, snap-fit clips may be additionally arranged on a periphery of an edge of the base plate 2, and those skilled in the art may change the number of the snap-fit clips to 1, 2, 3, 4, and etc. according to an actual situation. Slots capable of matching the snap-fit clips are formed at positions, corresponding to the snap-fit clips, on the cooling fan 8, and then the snap-fit clips on the base plate 2 are directly inserted into the slots on the cooling fan 8, to connect the base plate 2 and the cooling fan 8. During fixation in the magnetic attraction mode, magnetic sheets may be additionally arranged on a periphery of an edge of the base plate 2, and those skilled in the art may change the number of the magnetic sheets to 1, 2, 3, 4, and etc. according to an actual situation. Opposite-polarity magnetic sheets are arranged at positions, corresponding to the magnetic sheets, on the cooling fan 8, and then the magnetic sheets on the base plate 2 are directly aligned with the opposite-polarity magnetic sheets on the cooling fan 8, to connect the base plate 2 and the cooling fan 8.

Of course, the embodiment merely provides illustrative examples of fixed and detachable connection modes, but is not intended to limit this. Those skilled in the art may make modifications according to actual circumstances, provided that the same technical effects may be achieved.

Further, in some embodiments, a testing device further includes a temperature detection assembly and an airflow guiding component. The temperature detection assembly is configured to detect overall temperature distribution of the heat dissipation mechanisms 3, and the airflow guiding component is arranged on the cooling fan 8. Specifically, the airflow guiding component may automatically rotate, and the temperature detection assembly is in communication connection with the airflow guiding component. The temperature detection assembly is suitable for detecting a temperature in each detection area on the heat dissipation mechanisms 3. The airflow guiding component may rotate according to the temperature in each detection area, and adjust a specific airflow guiding direction through rotation.

Specifically, when an actual temperature of a detection area is higher than a preset temperature, the temperature detection assembly controls the airflow guiding component to rotate, whereby a heat dissipation airflow cools the detection area.

During actual operation, each heat dissipation mechanism 3 is divided into different areas first, and then a coordinate system is established by taking a center of the heat dissipation mechanism 3 as an original point, the length direction of the heat dissipation mechanism 3 as a longitudinal axis, and a width direction of the heat dissipation mechanism 3 as a horizontal axis. In this way, the temperature of each detection area on the heat dissipation mechanisms 3 is detected through the temperature detection assembly. Because each detection area has a respective coordinate interval, when an actual temperature of a certain detection area is higher than the preset temperature, the coordinate interval of the detection area is required to be acquired first, then the airflow guiding component is controlled to rotate, and the heat dissipation airflow dissipates heat according to a specified range of the coordinate interval, until the temperature of the detection area is lower than the preset temperature again.

With this configuration, by arranging the temperature detection assembly and the airflow guiding component, when the temperature of a certain area on the heat dissipation mechanisms 3 is detected to be higher, the airflow guiding component may be controlled to rotate, and the heat dissipation airflow precisely cools the detection area, to completely achieve automation.

Further, in some embodiments, the temperature detection assembly includes a control module and infrared sensors, which are in communication connection. A plurality of infrared sensors may be distributed in an array, or arranged at specific positions. Specifically, in the embodiment of the present disclosure, after the coordinate system is established, the temperature of each detection area on the heat dissipation mechanisms 3 is detected through the infrared sensors. Because each detection area has a respective coordinate interval, when the actual temperature of a certain detection area is higher than the preset temperature, the control module is required to acquire the coordinate interval of the detection area first, then the control module controls the cooling fan 8 to dissipate heat according to the specified range of the coordinate interval, until the temperature of the detection area is lower than the preset temperature again.

As a preferred implementation, temperature signals may also be processed into a temperature distribution map, one or more prioritized areas requiring focused cooling may be identified. For example, if a temperature of area A is 80° C., and temperatures of other areas are lower than 40° C., then the area A is identified as a prioritized area requiring focused cooling, and other areas are considered as specific areas for subsequent cooling as needed.

Further, those skilled in the art may make modifications to the number of the infrared sensors. The embodiment merely provides an illustrative example, but is not intended to limit this, provided that the same technical effects may be achieved.

Further, in some embodiments, as shown in FIG. 10, the mainboard liquid cooling device further includes a water pump assembly 9. The water pump assembly 9 is arranged on the liquid cooling base 12, and is communicated with the coolant manifold 11.

A control element of the water pump assembly 9 may be arranged on a side wall of a server, or integrated on a control board of the server, to be further controlled by a control module of the server. In actual application, the technical personnel may view an actual operating temperature of each device to be cooled 6 on the base plate 2 through a monitoring panel of the server, and then adjust the water pump assembly 9 according to an actual situation.

In the embodiment of the present disclosure, by arranging the water pump assembly 9, the technical personnel may adjust a flow rate of the liquid cooling medium according to the actual operating temperature of the device to be cooled 6, thereby preventing a problem that the liquid cooling medium fails to cool the device to be cooled 6 timely due to a rapid temperature change of the device to be cooled 6. After adjustment of the flow rate of the liquid cooling medium, the water pump assembly 9 may drive the liquid cooling medium to cool the device to be cooled 6 at a corresponding temperature, so as to ensure normal operation of the device to be cooled 6.

Further, in some embodiments, as shown in FIG. 10, the water pump assembly 9 includes a water pump 91 and a fixing plate 92. Specifically, in the embodiment of the present disclosure, the water pump 91 is arranged on the liquid cooling base 12, and the water pump 91 is communicated with the coolant manifold 11. The fixing plate 92 covers the water pump 91, and the fixing plate 92 is connected with the liquid cooling base 12. The fixing plate 92 may be made of a resilient metal material, and the fixing plate 92 may also fix the water pump 91 in various detachable modes, such as screw fixation, snap-fit clip fixation, and the like.

In the embodiment of the present disclosure, the fixing plate 92 is arranged, and the water pump 91 may be fixed to the liquid cooling base 12 in a detachable connection mode, thereby facilitating maintenance and replacement of the water pump 91 by the technical personnel. Compared with other connection modes, the detachable connection mode may simplify mounting and dismounting steps, thereby improving the working efficiency of the technical personnel.

Further, in some embodiments, the water pump assembly 9 further includes a temperature sensor. The temperature sensor is arranged on the heat sink 31, and is in communication connection with the water pump 91. The temperature sensor is configured to detect a current temperature of the heat sink 31, and the water pump 91 adjusts the flow rate of the liquid cooling medium based on the current temperature.

In the embodiment of the present disclosure, the temperature sensor is arranged, and the temperature sensor may automatically control the water pump 91 to adjust the flow rate of the liquid cooling medium according to the actual operating temperature of the device to be cooled 6, to allow the actual temperature of the device to be cooled 6 to match an actual flow rate of the liquid cooling medium, thereby preventing the problem that the liquid cooling medium fails to cool the device to be cooled 6 timely due to the rapid temperature change of the device to be cooled 6. After adjustment of the flow rate of the liquid cooling medium, the water pump assembly 9 may drive the liquid cooling medium to cool the device to be cooled 6 at the corresponding temperature, so as to ensure normal operation of the device to be cooled 6.

Further, in some embodiments, as shown in FIG. 14, when the heat dissipation mechanisms 3 and the base mechanism 1 are arranged in parallel in the same plane, the handle 33 of one heat dissipation mechanism 3 is provided with a protrusion 332, and the handle 33 of the other heat dissipation mechanism 3 is provided with a groove 333 suitable for receiving the protrusion 332. When the pair of heat dissipation mechanisms 3 are stacked, the protrusion 332 on the handle 33 of one heat dissipation mechanism 3 is inserted into the groove 333 on the handle 33 of the other heat dissipation mechanism 3, and the pair of heat dissipation mechanisms 3 are retained at the maintenance positions. When two handles 33 are required to be separated from each other, the two handles are simply required to be reversely pulled to separate the protrusion 332 from the groove 333.

In the embodiment of the present disclosure, the handles 33 are provided with the protrusion 332 and the groove 333, and after two heat sinks 31 are lifted, the handles 33 of the two heat dissipation mechanisms 3 may be snap-fitted through the groove 333 and the protrusion 332 to achieve fixation. In this way, the two heat sinks 31 are prevented from rotating downward and falling, which facilitates memory maintenance and simplifies operation for technical personnel.

In a second aspect, the present disclosure also provides a data processing system. The data processing system includes a device to be cooled 6, and the mainboard liquid cooling device according to any one of the above implementations. The device to be cooled 6 is arranged in a space enclosed by the heat dissipation mechanisms 3, the base mechanism 1, and the base plate 2.

Although the embodiments of the present disclosure are described with reference to the drawings, those skilled in the art can make various modifications and variations without departing from the spirit and scope of the present disclosure, and such modifications and variations fall within the scope limited by the claims.

In the figures:
1: base mechanism;
11: coolant manifold;
12: liquid cooling base;
13: support seat;
14: resilient member;
2: base plate;
3: heat dissipation mechanism;
31: heat sink;
311: retention slot;
32: locating assembly;
321: locating pin;
322: locating hole;
33: handle;
331: snap-fit clip;
332: protrusion;
333: groove;
4: second foam pad;
5: first foam pad;
6: device to be cooled;
7: rotary mechanism;
71: connecting pipe;
72: rotary sleeve;
721: sleeve body;
722: internal threaded column;
723: waterproof part;
8: cooling fan;
9: water pump assembly;
91: water pump; and
92: fixing plate.

1. A mainboard liquid cooling device, comprising:
a base mechanism, configured to be fixed to a base plate, wherein a flow channel for a liquid cooling medium is formed in the base mechanism, and
at least one pair of heat dissipation mechanisms, rotatably connected to the base mechanism through rotary mechanisms; wherein the rotary mechanisms are of hollow structure, and wherein the heat dissipation mechanisms, the rotary mechanisms and the base mechanism form a liquid cooling loop;
wherein each of the rotary mechanisms comprises a connecting pipe and a rotary sleeve, the connecting pipe is communicated with the heat dissipation mechanisms, one end of the rotary sleeve is connected with the connecting pipe, the other end of the rotary sleeve is rotatably communicated with the base mechanism, and the rotary sleeve and the base mechanism are rotatably sealed from each other; and
wherein the heat dissipation mechanisms, the base mechanism and the base plate enclose a space for accommodating a device to be cooled.

2.-3. (canceled)

4. The mainboard liquid cooling device according to claim 1, wherein,
each of the heat dissipation mechanisms is provided with a first water outlet and a first water inlet;
the base mechanism is provided with a second water outlet and a second water inlet; and
the connecting pipe is connected with the first water outlets or the first water inlets;
wherein the other end of the rotary sleeve is rotatably and sealingly connected with the second water outlet or the second water inlet of the base mechanism.

5. The mainboard liquid cooling device according to claim 4, wherein the connecting pipe is in threaded connection with the first water outlets and waterproof parts are arranged between the connecting pipe and the first water outlets; or
the connecting pipe is in threaded connection with the first water inlets, and waterproof parts are arranged between the connecting pipe and the first water inlets.

6. The mainboard liquid cooling device according to claim 5, wherein the rotary sleeve comprises:
a sleeve body, which is a hollow-cylinder-shaped structure, wherein a first end portion of the sleeve body is configured to interface with the connecting pipe, and a second end portion of the sleeve body is configured to be rotatably and sealingly sleeved on the second water outlet or the second water inlet of the base mechanism, and
an internal threaded column, with a waterproof part sleeved thereon, wherein the internal threaded column extends into the sleeve body and protrudes from the first end portion to allow the waterproof part to be located between the internal threaded column and the first end portion, and a portion of the internal threaded column that protrudes from the first end portion is in threaded connection with the connecting pipe.

7. The mainboard liquid cooling device according to claim 6, wherein the waterproof part is a waterproof gasket or a waterproof adhesive coating.

8. The mainboard liquid cooling device according to claim 1, wherein the base mechanism comprises:
a liquid cooling base, configured to be fixed onto the base plate, and
a coolant manifold, arranged on the liquid cooling base, wherein the flow channel is disposed within the coolant manifold, and the heat dissipation mechanisms are movably connected to the coolant manifold.

9. The mainboard liquid cooling device according to claim 8, wherein the base mechanism further comprises:
at least two pairs of support seats, arranged on the base plate;
wherein when any of the heat dissipation mechanism is in a heat dissipation position, the any of the heat dissipation mechanism is abutted against a corresponding pair of the at least two pairs of the support seats.

10. The mainboard liquid cooling device according to claim 9, wherein the base mechanism further comprises:
ejecting members, each arranged on a corresponding one of the support seats, wherein
when the at least one pair of heat dissipation mechanisms move close to each other and are in the heat dissipation position, the heat dissipation mechanisms are abutted against and compress the ejecting members; and
wherein under an elastic force of the ejecting members, the heat dissipation mechanisms are ejected out of the heat dissipation position, and under an external force, the at least one pair of heat dissipation mechanisms move away from each other and are in a maintenance position.

11. The mainboard liquid cooling device according to claim 10, wherein each of the heat dissipation mechanisms comprises:
a heat sink, movably connected to the base mechanism, and
a locating assembly, arranged on the heat sink, wherein
when the at least one pair of heat dissipation mechanisms are in the heat dissipation position, the locating assembly has a first position for interlocking the at least one pair of heat dissipation mechanisms, and a second position for separating the at least one pair of heat dissipation mechanisms from each other; and
when the locating assembly is in the second position, under the elastic force of the ejecting members, the heat dissipation mechanisms are ejected out of the heat dissipation positions.

12. The mainboard liquid cooling device according to claim 11, wherein the locating assembly comprises:
a locating pin, arranged on one of the at least one pair of heat dissipation mechanisms, and
a locating hole, formed on the other one of the at least one pair of heat dissipation mechanisms;
wherein when the locating assembly is in the first position, the locating pin is configured to be inserted into the locating hole, to interlock the at least one pair of heat dissipation mechanisms, and when the locating assembly is in the second position, the locating pin is configured to be removed from the locating hole, to separate the at least one pair of heat dissipation mechanisms from each other.

13. The mainboard liquid cooling device according to claim 12, wherein each of heat dissipation mechanisms further comprises:
a handle, detachably arranged on the heat sink, wherein the locating hole is arranged on the handle; and
the handle is further provided with snap-fit clips, and the heat sink is provided with retention slots for receiving the snap-fit clips.

14. The mainboard liquid cooling device according to claim 11, further comprising a support member arranged on the heat sink.

15. The mainboard liquid cooling device according to claim 14, wherein the support member comprises at least one of:
a first foam pad, arranged on a bottom face of the heat sink, and abutted against the device to be cooled when the heat sink is in the heat dissipation position, to form a gap between the heat sink and the device to be cooled; or
a second foam pad, arranged on a side face of the heat sink, and abutted against the base plate when the heat sink is in the maintenance position.

16. The mainboard liquid cooling device according to claim 9, further comprising:
a water pump assembly, arranged on the liquid cooling base, and in communication with the coolant manifold.

17. The mainboard liquid cooling device according to claim 16, wherein the water pump assembly comprises:
a water pump, arranged on the liquid cooling base, and in communication with the coolant manifold, and
a fixing plate, covering the water pump, wherein the fixing plate is connected with the liquid cooling base.

18. The mainboard liquid cooling device according to claim 17, wherein the water pump assembly further comprises:
a temperature sensor, arranged on the heat sink, wherein the temperature sensor is in communication connection with the water pump, the temperature sensor is configured to detect a current temperature of the heat sink, and the water pump adjusts a flow rate of the liquid cooling medium according to the current temperature.

19. The mainboard liquid cooling device according to claim 13, wherein
the handle of one of the heat dissipation mechanisms is provided with a protrusion, and the handle of a second one of the heat dissipation mechanisms is provided with a groove for receiving the protrusion; and
when the at least one pair of heat dissipation mechanisms are stacked on each other, the protrusion on the handle of the one of the heat dissipation mechanisms is inserted into the groove on the handle of the second one of the heat dissipation mechanisms, and the at least one pair of heat dissipation mechanisms are retained in the maintenance position.

20. A data processing system, comprising a device to be cooled, and a mainboard liquid cooling device,
wherein the mainboard liquid cooling device comprises:
a base mechanism, configured to be fixed to a base plate, wherein a flow channel for a liquid cooling medium is formed in the base mechanism, and
at least one pair of heat dissipation mechanisms, rotatably connected to the base mechanism through rotary mechanisms; wherein the rotary mechanisms are of hollow structure, and wherein the heat dissipation mechanisms, the rotary mechanisms and the base mechanism form a liquid cooling loop;
wherein each of the rotary mechanisms comprises a connecting pipe and a rotary sleeve, the connecting pipe is communicated with the heat dissipation mechanisms, one end of the rotary sleeve is connected with the connecting pipe, the other end of the rotary sleeve is rotatably communicated with the base mechanism, and the rotary sleeve and the base mechanism are rotatably sealed from each other; and
wherein the heat dissipation mechanisms, the base mechanism and the base plate enclose a space for accommodating a device to be cooled; and
wherein the device to be cooled is arranged in a space enclosed by the heat dissipation mechanisms, the base mechanism and the base plate.

21. The mainboard liquid cooling device according to claim 6, wherein the internal threaded column is a hollow structure, whereby the sleeve body is in communication with the connecting pipe.

22. The mainboard liquid cooling device according to claim 9, wherein the support seats are arranged at equal intervals on two sides of the coolant manifold.
